(19) United States
(12) Patent Application Publication
(10) Pub. No.: US 2012/0126434 A1
(43) Pub. Date: May 24, 2012

(54) LIQUID RESIN COMPOSITION AND SEMICONDUCTOR DEVICE USING THE SAME

(76) Inventor: Masaya Koda, Tokyo (JP)

(21) Appl. No.: 13/387,901

(22) PCT Filed: Jul. 20, 2010
(86) PCT No.: PCT/JP2010/004648

§ 371 Date: Jan. 30, 2012

(30) Foreign Application Priority Data
Jul. 31, 2009 (JP) 2009-179249

(51) Int. Cl. H01L 29/02; C09D 163/00

(52) U.S. Cl. 257/788; 523/400; 257/E29.002

(57) ABSTRACT

Disclosed are a liquid resin composition which contains a (A) liquid epoxy resin, (B) an amine hardener, (C) core-shell rubber particles, and (D) an inorganic filler, wherein the content of the solid components with respect to the total liquid resin composition is equal to or more than 65% by weight, and a semiconductor device using the liquid resin composition.

### TECHNICAL FIELD

The present invention relates to a liquid resin composition and a semiconductor device using the same.

### BACKGROUND ART

In a flip chip type semiconductor devices, a semiconductor element (chip) and a substrate are electrically connected by solder bumps. In such a flip chip type semiconductor device, a liquid resin composition called underfill material is filled in the gap between the chip and the substrate to reinforce the periphery of the solder bumps, whereby the connection reliability is improved. In such a flip chip package filled with underfill in this manner, along with the application of Low-k chips and lead free solder bumps in recent years, there is a demand for improved low thermal expansion property and low elasticity in the underfill material in order to prevent the destruction of the Low-k layer and the cracking of the solder bumps due to heat stress.

In order to make the underfill material have low thermal expansion, it is important to increase the filler content. However, there are problems in that increasing the filler content also increases the viscosity of the underfill material, the filling property of the underfill into the gap between the chip and the substrate is deteriorated and productivity is deteriorated.

In order to solve such problems, for example, using large diameter filler may suppress the increase of viscosity which accompanies the increase of the filler content. However, sedimentation of the filler or clogging of the filler in the narrow gap between the chip and the substrate may lead to the problem of deterioration of the filling property.

Also, in order to lower the elasticity of the underfill material, the introduction of a liquid or solid rubber component is important. However, if the rubber component is a liquid, the glass transition temperature (Tg) thereof is decreased, and therefore, may not withstand practical use of the underfill material. In the case of a solid rubber component, there is a problem in that the viscosity of the underfill material is increased along with an increase in the content of the component.

Hitherto, techniques have been proposed to solve the deterioration of the filling property of underfill material accompanying an increase of the filler content (for example, Patent Document 1 and 2).

### RELATED DOCUMENT

### Patent Document

[Patent Document 1] Japanese Laid-open Patent Publication No. 2005-119929
[Patent Document 2] Japanese Laid-open Patent Publication No. 2003-137529

### DISCLOSURE OF THE INVENTION

However, in the technology described in the above patent documents, sufficient underfill characteristics were not exhibited when the solid rubber particles were added because the balance of filler and solid rubber was not sufficiently considered.

The object of the present invention is, to provide a liquid resin composition for which the low thermal expansion property and low elasticity at a room temperature are good, and which is also excellent in balance with the filling property in a narrow gap, in a flip chip type semiconductor device.

These problems are solved by the following (1) to (11) described in the present invention.

(1) A liquid resin composition which contains (A) a liquid epoxy resin, (B) an amine hardener, (C) core-shell rubber particles, and (D) an inorganic filler, wherein the content of the solid components is equal to or more than 65% by weight with respect to the total liquid resin composition.

(2) The liquid resin composition according to (1), wherein the content of (C) the core-shell rubber particles is equal to or more than 1% by weight and equal to or less than 30% by weight with respect to the solid component of the liquid resin composition.

(3) The liquid resin composition according to (1) or (2), wherein (C) the core-shell rubber particles are core-shell silicone rubber particles.

(4) The liquid resin composition according to any one of (1) to (3), which further contains (E) a Lewis base or a salt thereof.

(5) The liquid resin composition according to (4), wherein contains (E) the Lewis base or the salt thereof are 1,8-diazabicyclo(5.4.0)undecene-7 or 1,5-diazabicyclo(4.3.0) nonene-5 and salts thereof.

(6) The liquid resin composition according to (4) or (5), wherein the content of (E) Lewis base or a salt thereof is equal to or more than 0.005% by weight and equal to or less than 0.3% by weight with respect to the total liquid resin composition.

(7) The liquid resin composition according to any one of (1) to (6), which contains at least one selected from tetra substituted phosphonium compounds, phosphobetaine compounds, adducts of phosphine compounds and quinone compounds, and adducts of phosphonium compounds and silane compounds as (F) a compound.

(8) The liquid resin composition according to any one of (1) to (7), which further contains silane coupling agent.

(9) The liquid resin composition according to any one of (1) to (8), wherein (A) liquid epoxy resin is bisphenol type epoxy resin.

(10) The liquid resin composition according to any one of (1) to (9), wherein the average particle diameter of (C) core-shell rubber particles is equal to or more than 0.01 μm and equal to or less than 20 μm.

(11) A semiconductor device which is produced by sealing the gap between a semiconductor chip and a substrate using the liquid resin composition according to any one of (1) to (10).

### EFFECT OF THE INVENTION

According to the present invention, it is possible, to provide a liquid resin composition for which the low thermal expansion property and low elasticity at a room temperature are good, and which is also excellent in balance the filling property in a narrow gap, in a flip chip type semiconductor device.

### DESCRIPTION OF EMBODIMENTS

### (Liquid Resin Composition)

The present invention relates to a liquid resin composition which contains (A) a liquid epoxy resin, (B) an amine hardener, (C) core-shell rubber particles, and (D) an inorganic filler, wherein the content of the solid components is equal to or more than 65% by weight with respect to the total liquid resin composition. Hereinafter, the present invention will be described in detail.

### (A) Liquid Epoxy Resin;

(A) The liquid epoxy resin of the present invention is not limited to a molecular weight or structure in particular as long as (A) the liquid epoxy resin has equal to or more than two epoxy groups per molecule.

Examples of (A) the liquid epoxy resin include epoxy resin such as novolac type epoxy resin such as phenol novolac type epoxy resin and cresol novolac type epoxy resin and the like; bisphenol type epoxy resin such as bisphenol A type epoxy resin and bisphenol F type epoxy resin and the like; aromatic glycidyl amine type epoxy resin such as N,N-diglycidylaniline, N,N-diglycidyltoluidine, diaminodiphenylmethane type glycidylamine and aminophenol type glycidyl amine and the like; hydroquinone type epoxy resin; biphenyl type epoxy resins; stilbene type epoxy resins; tri-phenol methane type epoxy resin; tri-phenolpropane type epoxy resin; alkyl-modified tri-phenolmethane type epoxy resin; triazine core containing epoxy resin; dicyclopentadiene-modified phenol type epoxy resin; naphthol type epoxy resin; naphthalene type epoxy resin; and aralkyl type epoxy resin such as phenol aralkyl type epoxy resin with phenylene and/or biphenylene skeleton, naphthol aralkyl type epoxy resin with phenylene and/or biphenylene skeleton and the like; and aliphatic epoxy resin such as alicyclic epoxy such as vinylcyclohexene dioxide, dicyclopentadiene oxide, alicyclic diepoxy-adipate and the like.

In addition, an epoxy resin, which contains a structure in which a glycidyl structure or glycidylamine structure are bonded to an aromatic ring, is more preferable since heat resistance, mechanical properties and moisture resistance are increased. It is even more preferable to limit the amount of aliphatic or alicyclic epoxy resin to be used since the reliability and especially the adhesive property are lowered. They may be used either alone or as a mixture of two or more.

Since liquid resin composition in the present invention is liquid at room temperature, in the case in which (A) epoxy resin contains only one type of (A) epoxy resin, that one type (A) epoxy resin is liquid at room temperature. In the case in which (A) epoxy resin contains equal to or more than two types of (A) epoxy resin, the entire mixture of all the (A) epoxy resin with equal to or more than two types of epoxy resin is liquid at room temperature. Therefore, in the case in which epoxy resin is a combination of equal to or more than two types of (A) epoxy resin, (A) epoxy resin may be a combination of epoxy resins which are all liquid at room temperature. Or, even if part of the epoxy resin is solid at room temperature, as long as the mixture becomes liquid at room temperature as a result of mixing it with a liquid epoxy resin at room temperature, a combination of liquid epoxy resin at room temperature and solid epoxy resin at room temperature may be used. Further, in the case in which (A) epoxy resin is a combination of equal to or more than two types of epoxy resin, it is not necessary that the liquid resin composition is produced by mixing other components after all of the epoxy resins used are mixed. And the liquid resin composition may be produced by separately mixing the epoxy resins used.

In the present invention, the fact that (A) epoxy resin is liquid at room temperature means that the mixture is liquid at room temperature when all of the epoxy resins used as epoxy resin components (A) are mixed. Further, in the present invention, room temperature means 25° C. and liquid means that resin composition has liquidity.

The content of the (A) epoxy resin is not particularly limited thereto but is preferably equal to or more than 5% by weight and equal to or less than 30% by weight and particularly preferably equal to or more than 5% by weight and equal to or less than 20% by weight. If the content is within the above range, the reactivity, heat resistance of the composition, mechanical strength, and flow characteristics at the time of sealing are excellent.

(B) Amine hardener;

(B) Amine hardener used in the present invention is not limited to a specific structure as long as amine hardener may harden epoxy resin.

Examples of (B) the amine hardener include aliphatic polyamines such as diethylenetriamine, triethylenetetramine, tetraethylenepentamine, m-xylenediamine, trimethylhexamethylenediamine, 2-methylpentamethylenediamine; alicyclic polyamines such as isophoronediamine, 1,3-bis(aminomethyl)cyclohexane, bis(4-amino-cyclohexyl)methane, norbornenediamine, 1,2-diaminocyclohexane and the like; piperazine-type polyamines such as N-aminoethylpiperazine, 1,4-bis(2-amino-2-methylpropyl)piperazine and the like; aromatic polyamines such as diaminodiphenylmethane, m-phenylenediamine, diaminodiphenyl sulfone, diethyl toluene diamine, trimethylene bis(4-aminobenzoate), polytetramethylene oxide-di-P-aminobenzoate and the like.

These amine hardeners may be used either alone or as a mixture of two or more.

Also, hardeners such as aromatic amines, aliphatic amines, solid amines, phenolic hardeners and anhydrides and the like may be used if the effect achieved is within the scope of the present invention.

Furthermore, for use as a sealing compound of the semiconductor device, an aromatic poly amine type hardener is more preferable since heat resistance, electrical properties, mechanical properties, adhesive properties, and moisture resistance are increased. Furthermore, in the case in which liquid resin composition of the present invention is used as underfill, it is more preferable that it be liquid at room temperature (25° C.).

The content of (B) the amine hardener is not particularly limited thereto, but is preferably equal to or more than 5% by weight and equal to or less than 30% by weight and particularly preferably equal to or more than 5% by weight and equal to or less than 20% by weight. If the content is within the above range, the reactivity, mechanical properties, and heat resistance of the composition are excellent.

The ratio of active hydrogen equivalent of (B) the amine hardener to epoxy equivalent of (A) the epoxy resin is preferably equal to or more than 0.6 and equal to or less than 1.4 and is particularly preferably equal to or more than 0.7 and equal to or less than 1.3. If active hydrogen equivalent of the (B) amine hardener is within the above range, the reactivity and heat resistance of the composition are particularly improved.

(C) Core-Shell Rubber Particles;

Components of (C) Core-shell rubber particles of the present invention are not limited thereto as long as (C) Core-shell rubber particles are spherical and are able to lower the elasticity of the resin composition.

For example, acrylic rubber, silicone rubber, urethane rubber, styrene-butadiene rubber, butadiene rubber and the like may be selected. Among these, silicone rubber is more preferred. Core-shell rubber particles using silicone rubber is core-shell silicone rubber particles where the surface of silicone rubber particles is covered on a silicone resin.

The glass transition temperature of the core unit of the (C) core-shell rubber particles is preferably lower than the glass transition temperature of the shell unit and lower than room temperature. The Core unit and the shell unit do not have to have the same kind of rubber. Combination is possible in which the core unit is silicone rubber and the shell unit is acrylic rubber or the core unit is butadiene rubber and shell unit is acrylic rubber.

Furthermore, in the present invention, the core-shell rubber particles are the particles that have a core unit in the center and a shell unit which covers the core unit. “Cover” is not limited to continuous covering of the entire outer surface of the core unit and includes partially covering or discontinuous covering or unevenly covering.

(C) The core-shell rubber particles are preferably spherical or substantially spherical since they are not easily aggregated. In addition, the average particle diameter of (C) the core-shell rubber particles is preferably equal to or more than 0.01 μm and equal to or less than 20 μm and is particularly preferably equal to or more than 0.1 μm and equal to or less than 5 μm. When the average particle diameter is equal to or more than the lower limit value, the increase of cohesion may be reduced and the decrease of liquidity due to the increase of viscosity may be suppressed. Also by being equal to or less than the upper limit value, the occurrence of the resin clogging may be suppressed even in narrow gaps.

The additive amount of (C) the core-shell rubber particles is not particularly limited thereto. However, for the solid component in the liquid resin composition, it is preferably equal to or more than 1% by weight and equal to or less than 30% by weight, more preferably equal to or more than 3% by weight and equal to or less than 20% by weight, and even more preferably equal to or more than 3% by weight and equal to or less than 13% by weight. When the additive amount of (C) the core-shell rubber particles is equal to or more than the lower limit value, low elasticity is achieved. Also when the additive amount is equal to or less than the upper limit value, a uniform dispersion is yielded and thereby the overall strength of the resin composition is increased.

### (D) Inorganic Filler;

(D) an inorganic filler of the present invention improves mechanical strength such as fracture toughness, thermal time dimensional stability, and moisture resistance. Therefore, by including the inorganic filler in the liquid resin composition, the reliability of semiconductor device is particularly improved.

Examples of (D) the inorganic filler include silicates such as talc, baked clay, unbaked clay, mica, glass and the like; oxides such as titanium oxide, alumina, silica powder such as fused silica (fused spherical silica, fused flake silica), synthetic silica, crystalline silica, and the like; carbonates such as calcium carbonate, magnesium carbonate, hydrotalcite and the like; hydroxides such as aluminum hydroxide, magnesium hydroxide, calcium hydroxide and the like; sulfates or sulfites such as barium sulfate, calcium sulfate, calcium sulfite and the like; borates such as zinc borate, barium metaborate, aluminum borate, calcium borate, sodium borate and the like; nitrides such as aluminum nitride, boron nitride, silicon nitride and the like. (D) These inorganic fillers may be used either alone or as a mixture of two or more. In the above, fused silica, crystalline silica, and synthetic silica powder are preferable since the heat resistance, moisture resistance and strength of the resin composition may be improved.

The shape of (D) the inorganic filler is not limited thereto. However, the spherical shape is preferable from the viewpoint of viscosity and liquidity characteristics.

The maximum particle diameter and average particle diameter of (D) the inorganic filler are not particularly limited thereto. However, a maximum particle diameter equal to or less than 25 μm and an average particle diameter equal to or more than 0.1 μm and equal to or less than 10 μm are preferable. The maximum particle diameter and the average particle diameter equal to or less than the upper limit value improves the effect of suppressing partial non filling or poor filling due to filler clogging when liquid resin composition flows to a semiconductor device. Also, the average particle diameter equal to or more than the lower limit enhances the filling property appropriately lowering the viscosity of the liquid resin composition.

The additive amount of (D) the inorganic filler is not particularly limited thereto. However, for the solid component of the liquid resin composition, it is preferably equal to or more than 70% by weight and equal to or less than 99% by weight and more preferably equal to or more than 80% by weight and equal to or less than 98% by weight. The additive amount being equal to or more than the lower limit value may achieve low linear expansion. Also the additive amount being equal to or less than the upper limit may suppress an increase of the elastic modulus.

In the present invention, the solid component in the liquid resin composition is a component which is solid at room temperature and not soluble in epoxy resin. The solid component in the liquid resin composition of the present invention corresponds to two types, which are (D) inorganic filler and (C) core-shell rubber particles.

In the present invention, the content of the solid component contained in the liquid resin composition is preferably equal to or more than 65% by weight, and more preferably equal to or more than 65% by weight and equal to or less than 80% by weight. The content of solid component being equal to more than 65% by weight increases the effect of improving the reliability of the semiconductor device. The content of the solid compound being equal to less than 80% by weight is excellent in balance between the filling property and the reliability in a narrow gap.

### Other Components;

The liquid resin composition of the present invention preferably contains (E) Lewis base or a salt thereof other than the above components in order to make a high content of the solid components possible.

Examples of the (E) Lewis base or a salt thereof include amine compound or a salt thereof such as 1,8-diazabicyclo(5.4.0)undecene-7, 1,5-diazabicyclo(4.3.0)nonene-5,1,4-diazadicyclo(2.2.2)octane, imidazoles, diethylamine, triethylenediamine, benzyldimethylamine, 2-(dimethylaminomethylphenol), 2,4,6-tris(dimethylaminomethyl)phenol and the like; and phosphine compounds such as triphenylphosphine, phenylphosphine, diphenylphosphine and the like. Among these, tertiary amine compounds such as benzyldimethylamine, 2-(dimethylaminomethylphenol), 2,4,6-tris(dimethylaminomethyl)phenol, imidazoles, 1,8-diazabicyclo(5.4.0)undecene-7, 1,5-diazabicyclo(4.3.0)nonene-5, and 1,4-diazadicyclo(2.2.2)octane or salts thereof are preferred. 1,8-diazabicyclo(5.4.0)undecene-7 and 1,5-diazabicyclo(4.3.0)nonene-5 or salts thereof are particularly preferred.

In the case in which (E) is the salt of a Lewis base, it may be, specifically, a phenol salt of the Lewis base and a phenol salt of 1,8-diazabicyclo(5.4.0)undecene-7.

The content of (E) the Lewis base and the salt thereof is not particularly limited thereto. However, it is preferably equal to or more than 0.005% by weight and equal to or less than 0.3% by weight with regard to the total liquid resin composition, more preferably equal to or more than 0.01% by weight and equal to or less than 0.2% by weight with regard to the total liquid resin composition, and even more preferably equal to or more than 0.02% by weight and equal to or less than 0.1% by weight with regard to the total liquid resin composition. The content being equal to or more than the lower limit value may achieve a good filling property in narrow gap since the content of the solid component is favorable. Also, the content being equal to or less than the upper limit value decreases the viscosity of liquid resin composition and may obtain favorable content of the solid component.

(E) the Lewis base or a salt thereof is not particularly limited thereto, but is preferably premixed with (A) epoxy resin and/or (B) epoxy resin hardener before producing the liquid resin composition of the present invention. Dispersibility of (E) the Lewis base or a salt thereof into (A) epoxy resin and/or (B) epoxy resin hardener is enhanced and therefore enables the introduction of more solid components.

“Premix” is stirring and mixing at room temperature and there is no particular upper limit on the stirring and mixing time. However, it is preferable to stir and mix for equal to or more than one hour from the viewpoint of homogeneously dispersing (E) the Lewis base or a salt thereof into (A) the epoxy resin and/or (B) epoxy resin hardener.

In the case in which (E) the Lewis base or a salt thereof is premixed with (A) epoxy resin and/or (B) epoxy resin hardener, improvement of the filling property in narrow gap is excellent particularly when content of (D) the inorganic filler is high. That is, by improving dispersibility into (A) epoxy resin and/or (B) epoxy resin hardener, it is possible to improve the filling property in narrow gap through improving wettability with respect to the semiconductor element and substrate in the flip chip packaging type semiconductor device.

In addition, as (F) compounds, it is preferable to include phosphobetaine compounds, adducts of phosphine compounds and quinone compounds, and adducts of phosphonium compounds and silane compounds. Including (F) these compounds have the effect of making a high content of solid components possible.

Tetra substituted phosphonium compounds of (F) compounds are, for example, compounds represented in the following general formula (1).

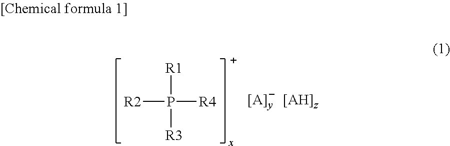

(In general formula (1), P is a phosphorous atom. R1, R2, R3 and R4 are aromatic groups or alkyl groups. A is an anion of the aromatic compound of which an aromatic ring has at least one functional group selected from hydroxyl group, carboxyl group and thiol group. AH is an aromatic compound of which an aromatic ring has at least one functional group selected from hydroxyl group, carboxyl group and thiol group. x and y are integers of 1 to 3, z is an integer of 0 to 3, and x=y)

In general formula (1), it is preferable that R1, R2, R3, and R4 are aromatic groups or alkyl groups having 1 to 10 carbon atoms.

In compounds represented in general formula (1), it is preferable that R1, R2, R3, and R4 bonded to a phosphorus atom are phenyl groups, AH is a compound having a hydroxyl group bonded to an aromatic ring, that is, phenols, and A is an anion of the phenols from the view point of increasing the effect of making high content of the solid components possible.

Phosphobetaine compounds of (F) compounds may be, for example, the compounds represented in the following general formula (2).

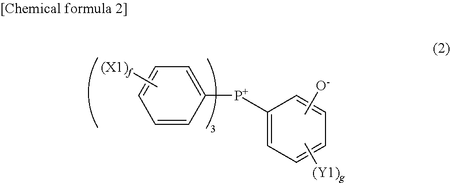

(In general formula (2), P is a phosphorous atom, X1 is an alkyl group having 1 to 3 carbon atoms, and Y1 is a hydroxyl group. f is an integer of 0 to 5 and g is an integer of 0 to 3.)

Adducts of phosphine compounds and quinone compounds of compounds (F) may be, for example, the compounds represented in the following general formula (3).

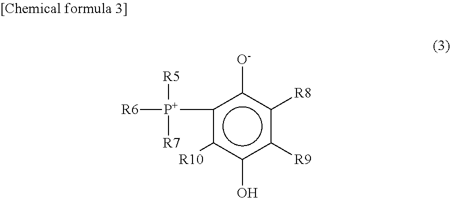

(In general formula (3), P is a phosphorous atom. R5, R6 and R7 are alkyl groups having 1 to 12 carbon atoms or aryl groups having 6 to 12 carbon atoms, which may be same as or different from each other. R8, R9 and R10 are hydrogen atoms or hydrocarbon group having 1 to 12 carbon atoms, which may be same as or different from each other and, may have a cyclic structure with R8 and R9 binding to each other.)

The phosphine compound used in adducts of phosphine compounds and quinone compounds of (F) compounds preferably is a compound, for example, which is unsubstituted or which have substituents such as an alkyl group or an alkoxyl group and the like in a cyclic ring such as triphenylphosphine, tris(alkyl phenyl)phosphine, tris(alkoxyphenyl)phosphine, tri-naphthylphosphine, tris(benzyl)phosphine and the like. Substituents such as an alkyl group or an alkoxyl group preferably have 1 to 6 carbon atoms. Triphenylphosphine is preferred from the viewpoint of availability.

The quinone compounds used in adducts of phosphine compounds and quinone compounds of (F) compounds includes o-benzoquinone, p-benzoquinone, anthraquinones and the like. Among these, p-benzoquinone is preferred from the viewpoint of storage stability.

Adducts of phosphonium compounds and silane compounds of (F) compounds may be, for example, compounds represented in the following general formula (4).

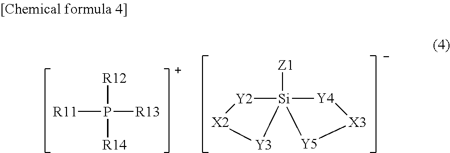

(In general formula (4), P is a phosphorous atom and Si is a silicon atom.

R11, R12, R13 and R14 are, respectively, organic groups having an aromatic ring or heterocyclic group or aliphatic groups having an aromatic ring or heterocyclic group, which may be same as or different from each other. In general formula (4), X2 is an organic group which is bonded to Y2 and Y3 groups. In general formula (4), X3 is an organic group which is bonded to Y4 and Y5 groups. Y2 and Y3 represent groups made by proton donor emitting protons and Y2 and Y3 groups in the same molecule bind with a silicon atom to form a chelate structure. Y4 and Y5 represent groups made by proton donor emitting protons and Y4 and Y5 groups in the same molecule bind with a silicon atom to form a chelate structure. X2 and X3 may be same as or different from each other and Y2, Y3, Y4 and Y5 may be same as or different from each other. Z1 is an organic group having an aromatic ring or a heterocyclic ring or aliphatic group having an aromatic ring or a heterocyclic ring.

In general formula (4), examples of R11, R12, R13, and R14 include a phenyl group, a methylphenyl group, a methoxyphenyl group, a hydroxyphenyl group, a naphthyl group, a hydroxylnaphthyl group, a benzyl group, a methyl group, an ethyl group, an n-butyl group, an n-octyl group, and a cyclohexyl group and the like. Among these, an aromatic group having substituents or unsubstituted aromatic group such as a phenyl group, a methylphenyl group, a methoxyphenyl group, a hydroxyphenyl group, a hydroxy naphthyl group is more preferable.

Groups represented as Y2-X2-Y3-, and —Y4-X3-Y5- in general formula (4) are constituted by groups where a proton donor emits two protons. These proton donors, that is, compounds before the two protons are emitted, include, for example, catechol, pyrogallol, 1,2-dihydroxynaphthalene, 2,3-dihydroxynaphthalene, 2,2′-biphenol, 1,1′-bi-2-naphthol, salicylic acid, 1-hydroxy-2-naphthoic acid, 3-hydroxy-2-naphthoic acid, chloranilic acid, tannic acid, 2-hydroxybenzyl alcohol, 1,2-cyclohexanediol, 1,2-propanediol and glycerin and the like. Among these, catechol, 1,2-dihydroxynaphthalene and 2,3-dihydroxynaphthalene are more preferable.

Z1 in general formula (4) represents an organic group having an aromatic ring or heterocyclic ring or an aliphatic group having an aromatic ring or heterocyclic ring, and a specific example of Z1 includes aliphatic hydrocarbon groups such as a methyl group, an ethyl group, a propyl group, a butyl group, a hexyl group and an octyl group and the like; aromatic hydrocarbon groups such as phenyl group, benzyl group, naphthyl group and biphenyl group and the like; reactive substituents such as a glycidyloxypropyl group, a mercaptopropyl group, an aminopropyl group and a vinyl group and the like. Among these, a methyl group, an ethyl group, a phenyl group, a naphthyl group and a biphenyl group are more preferable from the viewpoint of thermal stability.

The additive amount of (F) compound is not particularly limited thereto. However, with respect to the total liquid composition, it is preferably equal to or more than 0.005% by weight and equal to or less than 0.3% by weight, and more preferably equal to or more than 0.01% by weight and equal to or less than 0.2% by weight. The content being equal to or more than the lower limit value may achieve a good filling property in narrow gap since the content of the solid component is favorable. Also the content being equal to or less than the upper limit value decreases the viscosity of the liquid resin composition and obtains a favorable content of solid component.

The liquid resin composition of the present invention may use additives such as a coupling agent, a liquefied low-stress agent, a diluting agent, a pigment, a flame retardant, a leveling agent, a defoaming agent, and the like other than the components described above such as (A) epoxy resin and (B) amine hardener.

In the liquid resin composition of the present invention, the components and additives described above may be dispersed and kneaded using devices such as planetary mixer, triple rollers, double heated rollers, raikai mixer, and then may be prepared by defoaming the mixture under vacuum.

### (Semiconductor Device)

The semiconductor device of the present invention, specifically a flip chip type semiconductor device, is prepared using the liquid resin composition of the present invention. In this flip chip type semiconductor device, a semiconductor element (semiconductor chip) equipped with a solder electrode is connected to the substrate, and the gap between the semiconductor chip and the substrate is sealed. Generally, in this case, in area outside the unit where solder electrode of the substrate is jointed, solder resist is formed so that the solder does not flow down.

The semiconductor device of the present invention is prepared as follows, for example.

First, the semiconductor chip equipped with solder electrode is connected to the substrate and the liquid resin composition of the present invention is filled into the gap between the semiconductor chip and the substrate.

As a method of filling, a method using capillarity is commonly used. Specific examples of the method of filling include a method in which, after applying the liquid resin composition of the present invention on one side of the semiconductor chip, the liquid resin composition is poured into the gap between the semiconductor chip and the substrate using capillarity; a method in which, after applying the liquid resin composition of the present invention on two sides of the semiconductor chip, the liquid resin composition is poured into the gap between the semiconductor chip and the substrate using capillarity; and a method that, after opening a through-hole in the center unit of the semiconductor chip and applying the liquid resin composition of the present invention around the semiconductor chip, the liquid resin composition is poured into the gap between the semiconductor chip and the substrate using capillarity, and the like. Also, instead of applying the entire amount at once, a method of applying in twice may also be used. A method of potting, printing or the like may also be used.

Then, by hardening the filled liquid resin composition of the present invention, a semiconductor device, of which the gap between the semiconductor chip and the substrate is sealed by the hardener of the liquid resin composition of the present invention, may be obtained.

The hardening conditions are not particularly limited thereto. However, by heating at a temperature range of 100° C. to 170° C. for 1 to 12 hours, it may be hardened. It is also possible to perform heat hardening by changing temperatures in stages, such as, for example, heating for 1 hour at 100° C., and then continuing the heating for 2 hours at 150° C.

Examples of this type of semiconductor devices include a flip chip type semiconductor device, a cavity-down type Ball Grid Array (BGA), a Package on Package (POP) type Ball Grid Array (BGA), a Tape Automated Bonding (TAB) type Ball Grid Array (BGA), Chip Scale Package (CSP), and the like.

The present invention is not limited to an embodiment described above, and includes modifications, improvements and the like that may be achieved within the scope of the object of the present invention.

### EXAMPLES

Hereinafter, the present invention will be described in detail with reference to examples, but the present invention is not limited to these examples. Also blending amounts in the Examples and Comparative Examples are parts by weight.

### Example 1

The liquid resin composition for encapsulating is prepared through blending 100 parts by weight of bisphenol F type epoxy resin, 32 parts by weight of aromatic primary amine type hardener, 25 parts by weight of core-shell rubber particle C11, 310 parts by weight of inorganic filler, 4 parts by weight of silane coupling agent, 5 parts by weight of diluting agent, 0.1 parts by weight of flow improving agent, 0.05 parts by weight of colorant and mixing these by using a planetary mixer and triple roller, and then by defoaming the mixture under vacuum.

The liquid resin composition for encapsulating obtained is evaluated by the following evaluation methods and the results are presented in Table 1.

### [Evaluation Method of the Liquid Resin Composition for Encapsulating]

Viscosity: Viscosity (Pa·s) was measured using a TV-E type viscometer under the conditions of 25° C. and 5 rpm.
Glass transition temperature, linear expansion coefficient: Glass transition temperature (° C.) and linear expansion coefficient (ppm/° C.) were measured by measuring a liquid resin composition for encapsulating which was hardened into a square pillar shape using a thermo-mechanical analyzer (TMA).
Elastic Modulus: Elastic modulus (GPa) was measured by measuring a liquid resin composition for encapsulating which was hardened into a plate shape at room temperature (25° C.) and a frequency of 1 Hz using a Dynamic Mechanical Analyzer (DMA).

Next, the semiconductor device was prepared as follows using the obtained liquid resin composition for encapsulating.

A PHASE-2TEG wafer (wafer thickness of 0.35 mm) manufactured by Hitachi Ultra LSI using polyimide as a circuit protection film of the chip, on which lead-free solder of Sn, Ag and Cu composition as solder bumps was formed, and which was cut into 15 mm×15 mm pieces, was employed as a semiconductor chip.

A substrate having a glass epoxy substrate of 0.8 mmt equivalent FR5 manufactured by Sumitomo Bakelite Co., Ltd. used as a base, solder resist PSR4000/AUS308 manufactured by Taiyo Ink Manufacturing Co., Ltd. formed on both sides of the substrate and a gold plating pad correspond to the solder bump array formed on one side, and which was cut into 50 mm×50 mm pieces, was employed. As flux for connection, TSF-6502 (manufactured by Kester, rosin-based flux) was used.

In the assembly of the semiconductor devices, first, flux was uniformly coated with thickness of about 50 μm using a doctor blade on sufficiently smooth metal or glass plate, and the circuit surface of the chip was lightly contacted to the flux membrane using a flip chip bonder and then released so that flux in the solder bump was then transcribed, and the chip was compressed onto and bonded to the substrate. Next the solder bump is melted and bonded to prepare the semiconductor device by a heat treatment in an IR reflow furnace. Washing was performed using a cleaning solution after melting and bonding. Filling and encapsulating by the liquid resin composition for encapsulating was performed by heating the substrate loaded with the chip prepared on a hot plate of 110° C., applying the prepared liquid resin composition for encapsulating on one side of the chip and filling the gap. The liquid resin composition for encapsulating was heated and hardened for 120 minutes in an oven at 150° C. Then a semiconductor device with a chip thickness of 0.35 mm for use in evaluation testing was obtained. The obtained semiconductor device was evaluated by the following evaluation methods and the results are presented in Table 1.

### [Evaluation Method of the Semiconductor Device]

Filling property (liquidity): For the semiconductor device manufactured above, the occurrence of voids was checked where the liquid resin composition for encapsulating was filled using an ultrasonic test machine.

If filling defect voids were not observed, it was considered as “good” and if filling defect voids were observed, it was considered as “bad”.
Reflow resistance property: In a reflow resistance test, moisture absorption treatment of JEDEC Level 3 of the prepared semiconductor device (168 hours of treatment at 30° C. and relative humidity of 60%) was performed, IR reflow treatment (peak temperature 260° C.) was performed three times, the presence of peeling of the liquid resin composition for encapsulating inside the semiconductor device was confirmed by an ultrasonic test machine, and the presence of cracks in the surface of the liquid resin composition for encapsulating on a side unit of the chip was further observed using an optical microscope.

If peeling and cracking were not observed, it was considered as “good” and if peeling and cracking were observed, it was considered as “bad”.
Temperature cycle property: In a temperature cycle test, a semiconductor device on which the reflow test above was performed was subjected to temperature cycle treatments of (−55° C./30 minutes) and (125° C./30 minutes), the presence of peeling was confirmed using ultrasonic test machine at an interface of the semiconductor chips and the liquid resin composition for encapsulating in semiconductor devices every 250 cycles, and the presence of cracking was observed by observing the surface of the liquid resin composition for encapsulating on side unit of the chip using an optical microscope. The above temperature cycle test was finally performed up to 1000 cycles.

If peeling and cracking were not observed, it was considered as “good” and if peeling and cracking were observed, it was considered as “bad”.

### Example 2

Apart from the fact that core-shell rubber particles C12 with different particle diameters were used instead of core-shell rubber particles C11, a liquid resin composition was prepared by the same method as in Example 1. Using the obtained liquid resin composition, a liquid resin composition and the semiconductor device were evaluated in the same manner as in Example 1, and the results are presented in Table 1.

### Example 3 to 6

Apart from the fact that the blending amount of core-shell rubber particles C11 and the blending amount of inorganic filler were changed to the numbers presented in Table 1, a liquid resin composition was prepared by the same method as in Example 1. Using the obtained liquid resin composition, a liquid resin composition and the semiconductor device were evaluated in the same manner as in Example 1, and the results are presented in Table 1.

### Comparative Example 1

Apart from the fact that core-shell rubber particles C11 were not blended and the blending amount of inorganic filler was changed to the number presented in Table 1, a liquid resin composition was prepared by the same method as in Example 1. Using the obtained liquid resin composition, the liquid resin composition and the semiconductor device were evaluated in the same manner as in Example 1, and the results are presented in Table 1.

### Comparative Example 2

Apart from the fact that liquid polybutadiene was blended instead of the core-shell rubber particles C11 and the blending amount of inorganic filler was changed to a number presented in Table 1, a liquid resin composition was prepared by the same method as in Example 1. Using the obtained liquid resin composition, the liquid resin composition and the semiconductor device were evaluated in the same manner as in Example 1, and the results are presented in Table 1.

### Comparative Examples 3 and 4

Apart from the fact that the blending amount of core-shell rubber particles C11 and the blending amount of inorganic filler were changed to the numbers presented in Table 1, a liquid resin composition was prepared by the same method as in Example 1. Using the obtained liquid resin composition, the liquid resin composition and the semiconductor device were evaluated in the same manner as in Example 1, and the results are presented in Table 1.

In addition, the materials used in the Examples and Comparative Examples were as follows.
Bisphenol F type epoxy resin: made by Dainippon Ink and Chemicals Co., EXA-830LVP, bisphenol F type liquid epoxy resin, epoxy equivalent 161
Aromatic primary amine type hardener: made by Nippon Kayaku Co., Ltd., Kaya hard-AA, 3,3′-diethyl-4,4′-diaminodiphenylmethane, amine equivalent 63.5
Core-shell rubber particles C11: core-shell silicone rubber particles, made by Shin-Etsu Chemical Co., Ltd., KMP-605, core-shell particles where the surface of a silicone rubber particles is covered on a silicone resin, average particle size 2 μm
Core shell rubber particles C12: core-shell silicone rubber particles, made by Shin-Etsu Chemical Co., Ltd., KMP-600, core-shell rubber particles where the surface of a silicone rubber particles is covered on a silicone resin, average particle size 5 μm
Liquidpolybutadiene: made by Daicel Chemical Industries Ltd., PB3600
Inorganic filler: synthetic spherical silica, made by Admatechs Co., Ltd., ADMAFINE SO-E3, synthetic spherical silica, maximum particle diameter 24 μm or less, average particle diameter 1 μm
Silane coupling agent: epoxy silane coupling agent, made by Shin-Etsu Chemical Co., Ltd., KBM403E, γ-glycidoxypropyltrimethoxysilane
Colorant: made by Mitsubishi Chemical Corporation MA-600, carbon black
Diluting agent: made by Tokyo Chemical Industries Co., Ltd., (reagent) BCSA, ethylene glycol mono-normal-butyl ether acetate
Flow improving agent: 1,8-diazabicyclo(5.4.0)undecene-7(DBU)

TABLE 1

| | | Examples | | | | | | Comparative Examples | | | |
|---|---|---|---|---|---|---|---|---|---|---|---|
| | | 1 | 2 | 3 | 4 | 5 | 6 | 1 | 2 | 3 | 4 |
| Component | Bisphenol F type epoxy | 100 | 100 | 100 | 100 | 100 | 100 | 100 | 100 | 100 | 100 |
| [Parts by weight] | resin | | | | | | | | | | |
| | Aromatic primary amine | 32 | 32 | 32 | 32 | 32 | 32 | 32 | 32 | 32 | 32 |
| | type hardener | | | | | | | | | | |
| | Silane coupling agent | 4 | 4 | 4 | 4 | 4 | 4 | 4 | 4 | 4 | 4 |
| | Flow improving agent | 0.1 | 0.1 | 0.1 | 0.1 | 0.1 | 0.1 | 0.1 | 0.1 | 0.1 | 0.1 |
| | Colorant | 0.05 | 0.05 | 0.05 | 0.05 | 0.05 | 0.05 | 0.05 | 0.05 | 0.05 | 0.05 |
| | Diluting agent | 5 | 5 | 5 | 5 | 5 | 5 | 5 | 5 | 5 | 5 |
| | Inorganic filler | 310 | 310 | 400 | 530 | 290 | 370 | 210 | 610 | 240 | 125 |
| | Core-shell rubber | 25 | | 29 | 36 | 14 | 60 | | | 15 | 42 |
| | particles C11 | | | | | | | | | | |
| | Core-shell rubber | | 25 | | | | | | | | |
| | particles C12 | | | | | | | | | | |
| | Liquid polybutadiene | | | | | | | | 190 | | |
| Content of solid | Content of Core-shell | 5.2 | 5.2 | 5.1 | 5.1 | 3.1 | 10.5 | 0 | 0 | 3.8 | 13.6 |
| | rubber particles [% by | | | | | | | | | | |
| | weight] | | | | | | | | | | |
| | Content of inorganic | 65.0 | 65.0 | 70.0 | 74.8 | 65.0 | 64.7 | 59.8 | 64.8 | 60.5 | 40.5 |
| | filler[% by weight] | | | | | | | | | | |
| | Content of solid | 70.2 | 70.2 | 75.1 | 79.9 | 68.1 | 75.2 | 59.8 | 64.8 | 64.3 | 54.1 |
| | component in total liquid | | | | | | | | | | |
| | resin composition [% by | | | | | | | | | | |
| | weight] | | | | | | | | | | |
| | Content of core-shell | 7.5 | 7.5 | 6.8 | 6.4 | 4.6 | 14.0 | 0 | 0 | 5.9 | 25.1 |
| | particles in solid | | | | | | | | | | |
| | component [% by weight] | | | | | | | | | | |
| Evaluation results | viscosity [Pa · s] | 65 | 60 | 80 | 120 | 60 | 150 | 10 | 200 | 150 | 50 |
| | Glass transition | 80 | 80 | 80 | 80 | 80 | 80 | 80 | 60 | 80 | 80 |
| | temperature [° C.] | | | | | | | | | | |
| | Linear expansion | 23 | 23 | 21 | 20 | 24 | 21 | 32 | 30 | 30 | 30 |
| | coefficient [ppm/° C.] | | | | | | | | | | |
| | Elastic Modulus [GPa] | 9 | 9 | 10 | 11 | 10 | 8 | 8 | 7 | 9 | 5 |
| | Filling property (liquidity) | good | good | good | good | good | good | good | good | good | good |
| | Reflow resistance | good | good | good | good | good | good | good | bad | good | bad |
| | Temperature cycle | good | good | good | good | good | good | bad | — | bad | bad |

—: Since peeling occurred during the reflow resistance test, the temperature cycle test was not performed

### RESULTS

In Comparative Example 1 where core-shell rubber particles were not contained, peeling occurred during the temperature cycle test. In the case in which a liquid rubber component was contained instead of the core-shell rubber particles as in Comparative Example 2, the elastic modulus was reduced, however, the glass transition temperature was also decreased and peeling occurred during the reflow resistance test. Since peeling occurred during the reflow resistance test, the temperature cycle test was not performed. In the case of a solid component of less than 65% by weight as in Comparative Example 3, the linear expansion coefficient increased, and peeling occurred during the temperature cycling test as in Comparative Example 1. In the case of a Solid component of less than 65% by weight as in comparative example 4, the linear expansion coefficient increased, and peeling accompanying bump cracking occurred during the temperature cycle test.

In examples 1 to 6, since core-shell rubber particles were included and equal to or more than 65% by weight of solid components was included, low elasticity and low heat-expansion were achieved, therefore, peeling and cracking in the temperature cycle test did not occur. In a liquid resin composition containing a solid component which includes core-shell rubber particles equal to or more than 65% by weight, low elasticity and low heat expansion were achieved, therefore, it was possible to improve the reliability of the semiconductor device.

This application claims priority rights based on Japanese Patent Application No. 2009-179249 filed on Jul. 31, 2009 and all the disclosure thereof is incorporated herein.

1. A liquid resin composition comprising:
(A) a liquid epoxy resin;
(B) an amine hardener;
(C) core-shell rubber particles; and
(D) an inorganic filler,
wherein the content of the solid components is equal to or more than 65% by weight with respect to the total liquid resin composition.

2. The liquid resin composition according to claim 1,
wherein the content of (C) the core-shell rubber particles is equal to or more than 1% by weight and equal to or less than 30% by weight with respect to the solid component of the liquid resin composition.

3. The liquid resin composition according to claim 1,
wherein (C) the core-shell rubber particles are core-shell silicone rubber particles.

4. The liquid resin composition according to claim 1, further comprising:
(E) a Lewis base or a salt thereof.

5. The liquid resin composition according to claim 4,
wherein (E) the Lewis base or a salt thereof is 1,8-diazabicyclo(5.4.0)undecene-7 or 1,5-diazabicyclo(4.3.0)nonene-5 and salts thereof.

6. The liquid resin composition according to claim 4,
wherein the content of (E) the Lewis base or a salt thereof is equal to or more than 0.005% by weight and equal to or less than 0.3% by weight with respect to the total liquid resin composition.

7. The liquid resin composition according to claim 1, further comprising at least one selected from tetra substituted phosphonium compounds, phosphobetain compounds, adducts of phosphine compounds and quinone compounds, and adducts of phosphonium compounds and silane compounds as (F) a compound.

8. The liquid resin composition according to claim 1, further comprising a silane coupling agent.

9. The liquid resin composition according to claim 1, wherein (A) the liquid epoxy resin is a bisphenol type epoxy resin.

10. The liquid resin composition according to claim 1, wherein the average particle diameter of (C) the core-shell rubber particles is equal to or more than 0.01 μm and equal to or less than 20 μm.

11. A semiconductor device which is produced by sealing the gap between a semiconductor chip and a substrate using the liquid resin composition according to any one of claims 1 to 10.
